(19) United States
(12) Patent Application Publication
(10) Pub. No.: US 2006/0156983 A1
(43) Pub. Date: Jul. 20, 2006

(54) Low temperature, atmospheric pressure plasma generation and applications

(75) Inventors: Joel Penelon, Monrovia, MD (US); Sylvain Motycka, Ramonville St Agne (FR); Steve Babayan, Los Angeles, CA (US); Xiawan Yang, Boise, ID (US)

Correspondence Address: CANADY & LORTZ;ORIGIN LAW, 2540 HUNTINGTON DRIVE, SUITE 205, SAN MARINO, CA, 91108, US

(73) Assignee: Surfx Technologies LLC, Culver City, CA (US)

(21) Appl. No.: 11/227,724

(22) Filed: Sep. 14, 2005

Related U.S. Application Data
(60) Provisional application No. 60/645,546, filed on Jan. 19, 2005.
(60) Provisional application No. 60/682,336, filed on May 18, 2005.

(51) Int. Cl. B01J 19/08; C23F 1/00; C23C 16/00

(52) U.S. Cl. 118/723 E; 422/186.29; 156/345.47

(57) ABSTRACT

Devices and methods for generating a low temperature atmospheric pressure plasma are disclosed. A method of generating a low temperature atmospheric pressure plasma that comprises coupling a high-frequency power supply to a tuning network that is connected to one or more electrodes, placing one or more non-conducting housings between the electrodes, flowing gas through the one or more housings, and striking and maintaining the plasma with the application of said high-frequency power is described. A technique for the surface treatment of materials with said low temperature atmospheric pressure plasma, including surface activation, cleaning, sterilization, etching and deposition of thin films is also disclosed.

### CROSS-REFERENCE TO RELATED APPLICATIONS

This application claims the benefit under 35 U.S.C. §119(e) of the following U.S. provisional patent applications, which are both incorporated by reference herein:

U.S. Provisional Patent Application No. 60/645,546, filed Jan. 19, 2005, and entitled “METHOD AND APPARATUS FOR GENERATING A LOW TEMPERATURE, ATMOSPHERIC PRESSURE PLASMA AND USE THEREOF”, by Penelon et al.; and

U.S. Provisional Patent Application No. 60/682,336, filed May 18, 2005, and entitled “LOW-TEMPERATURE, REACTIVE GAS SOURCE AND METHOD OF USE”, by Penelon et al.

### BACKGROUND OF THE INVENTION

1. Field of the Invention

The invention is related to methods and apparatuses for generating plasmas. Particularly, the invention is related to methods and apparatuses for generating a low temperature, atmospheric pressure plasma, and its use for surface treatment and the deposition of thin films.

2. Description of the Related Art

Plasmas are used in materials manufacturing for a diverse range of processes, including surface activation, etching, cleaning, decontamination, and thin film coatings. Industrial plasmas operate either at low pressure (less than 5 Torr) or at atmospheric pressure. Examples of low-pressure plasmas are capacitive discharges, inductively coupled plasmas, and electron cyclotron resonance sources (see Lieberman and Lichtenberg, “Principles of Plasma Discharges and Materials Processing,” John Wiley & Sons, Inc., New York, 1994; and Chen, “Introduction to Plasma Physics and Controlled Fusion,” Plenum Press, New York, 1984). These tools are a standard feature in semiconductor fabrication plants. On the other hand, atmospheric pressure discharges fall into two main categories: thermal plasma torches, which exhibit gas temperatures exceeding 3000° C.; and non-equilibrium discharges, which operate near room temperature. See e.g., Schütze, et al., “The Atmospheric-Pressure Plasma Jet: A Review and Comparison to other Plasma Sources,” IEEE Transactions in Plasma Science, vol. 26, page 1685 (1998). Atmospheric pressure plasmas have the advantage of treating three-dimensional objects of any size or shape, and are well suited for continuous, in-line processing. In addition, they do not require vacuum systems, thereby reducing the equipment cost.

A plasma torch is essentially a direct current (DC) arc between two electrodes. See e.g., Fauchais et al., “Thermal Plasmas,” IEEE Transactions on Plasma Science, vol. 25, page 1258, (1997); Smith et al., “Thermal plasma materials processing—applications and opportunities,” Plasma Chemistry and Plasma Processing, vol. 9, page 135S, (1989); and Ramakrishnan et al., “Properties of electric arc plasma for metal cutting,” Journal of Appied Physics D, vol. 30, page 636 (1997). Gas is blown through the arc and out onto a substrate to be processed. The temperature is extremely high in the arc, and substrates can be melted if they spend too much time underneath the plasma jet. Arcs are not easily scaled up to treat large areas. Most importantly, the electrodes can be sputtered away, contaminating the material being treated. In addition, plasma torches require large amounts of power to operate, adding to the complexity of the equipment, and posing some risk of electrical shock.

U.S. Pat. No. 5,198,724, by Koinuma et al., describes a plasma source that contains concentric metal electrodes and is powered by a high frequency signal generator. The disadvantage of this source is that the plasma directly contacts the electrodes and may sputter off material, thereby contaminating the substrate being processed. This is confirmed in their experiments, in which they detect tungsten from the electrodes on the silicon and aluminum substrates after plasma exposure. The plasma density and in turn the reactive species density is not high in this device. For example, when the plasma was fed with 1.0 volume percent carbon tetrafluoride in helium, the silicon removal rate was only 0.2 microns per minute.

U.S. Pat. Nos. 5,977,715 and 6,730,238 by Li et al., are directed to low temperature, atmospheric pressure plasmas. These publications describe sources where the gas is directly in contact with the metal electrodes. As discussed above, this can result in sputtering of the electrodes and contamination of the wafer placed below the source. U.S. Pat. No. 5,977,715, describes a plasma source that requires two separate matching networks, one to strike the discharge, and another one to maintain it. Therefore, the design of this system is expensive and not versatile.

U.S. Pat. No. 5,961,772, by Selwyn, describes an atmospheric pressure plasma jet. This source comprises two concentric metal electrodes that are coupled to radio frequency power at 13.56 MHz. This design has several disadvantages: contamination may result from electrode sputtering; the plasma must be operated with at least 95 percent helium at high flow rates; and processing rates are relatively low. For example, Jeong et al., “Etching polyimide with a non-equilibrium atmospheric-pressure plasma jet,” Journal of Vacuum Science and Technology A, vol. 17, page 2581 (1999), indicates that the maximum polyimide etching rate achieved with the plasma jet is 8.0 microns per minute.

Low temperature, atmospheric pressure plasmas have been developed that use dielectric materials to cover the electrodes and prevent an arc from forming between them. These plasmas are referred to as coronas, or dielectric barrier discharges (DBDs). The discharge may be struck with DC, alternating current (AC), or high frequency power. Normally, the dielectric surfaces charge up during operation, and emit short-lived micro arcs that shoot across the gap. These micro arcs can be eliminated by feeding certain gases to the discharge and operating at low current densities, but this severely limits the operating range of the device. See e.g., Kogelschatz, “Filamentary, patterned, and diffuse barrier discharges,” IEEE Transactions on Plasma Science, vol. 30, page 1400 (2002); and U.S. Pat. Nos. 5,414,324 and 6,676,802, by Roth et al. One of the disadvantages of DBDs is that the reactive species densities are relatively low. Therefore, in order to get reasonable surface treatment rates, the substrate must be placed inside the discharge between the electrodes. This limits the type of objects that can be processed to thin sheets of material, such as plastic film. Processing three-dimensional objects is not readily achievable with this design.

U.S. Pat. No. 6,204,605, by Laroussi et al., presents a device in which the atmospheric pressure plasma is confined inside a non-conducting tube. The electrodes are thin metal strips or wires that are wrapped around the tube and connected to an AC power supply at 10 to 50 KHz. The problem with this design is that the electrodes do not efficiently couple the electric power into the gas, so that the fraction of the gas dissociating into reactive species is most likely small and not well suited for surface treatment.

U.S. Pat. No. 6,465,964, by Taguchi et al., describes an atmospheric pressure plasma that is produced in a non-conducting tube. Two power supplies are required, one to strike the discharge and another to sustain it. In addition, the device must be fed with a minimum of 20.0 volume percent helium in order to generate the plasma. The dual electrode design adds greatly to the complexity of this system. In addition, the metal electrode used to strike the plasma is inserted directly into the gas flow, thereby providing a potential source of contamination, as described earlier.

In view of the foregoing, there is a need in the art for a low temperature, atmospheric pressure plasma that avoids contamination of the gas from metal electrodes, that operates with any gas composition, preferably argon or nitrogen and a lesser amount of reactive gas molecules, and that generates a plasma beam with a high density of reactive species for the rapid surface treatment of three-dimensional objects of any size or shape. These and other needs are met by the present invention as detailed hereafter.

### SUMMARY OF THE INVENTION

To overcome the limitations in the prior art described above, and to overcome other limitations that will become apparent upon reading and understanding the specification, various embodiments of the present invention are directed to a technique for generating plasmas at atmospheric pressure and temperatures below 400° C., in which the ionized gas does not come into contact with the electrodes. For example, the technique may involve flowing a gas through a non-conducting housing, applying a high-frequency signal to one or both of the electrodes that are placed on the outside of the housing, and matching the impedance of the power input to the gas so as to strike and maintain a uniform, low temperature plasma. Radio frequency power at substantially 13.56 MHz is well suited for embodiments of the invention, although many other frequencies are also operable, as shall be understood by those skilled in the art.

One exemplary embodiment of the present invention comprises a device for generating the plasma at atmospheric pressure and temperatures below 400° C. This apparatus includes a non-conducting housing with a gas inlet and outlet, electrodes that are placed on the outer walls of the housing, a power supply operating at frequencies between approximately 1.0 and 500.0 MHz, and particularly at 13.56 MHz, and a matching network for efficiently coupling the electrical power into the electrodes. A particularly well-suited matching network for this embodiment is one that makes it possible to strike and maintain the plasma at substantially lower power inputs than in the prior art.

A typical embodiment of the invention comprises an atmospheric pressure plasma device including a housing of a dielectric material having a gas inlet and a gas outlet, a first electrode exterior to the housing, a second electrode exterior to the housing and opposed to the first electrode, and a high-frequency power supply coupled to at least one of the first electrode and the second electrode and operable to ionize at least a portion of a gas flowing from the gas inlet to the gas outlet of the housing to produce at least one reactive species flowing out of the gas outlet of the housing. The housing may have a tubular or a rectangular duct. The tubular duct may comprise an inner diameter approximately between 0.1 and 5.0 millimeters, whereas the rectangular duct may comprise an inner height approximately between 0.1 and 5.0 millimeters. The dielectric material of the housing may quartz or sapphire. Typically, the reactive species flowing out of the gas outlet of the housing has a temperature less than approximately 500° C.

The high-frequency power supply provides electrical power at n times of approximately 13.56 megahertz, where n is an integer ranging from 1 to 20. An impedance matching network may be used to couple the high-frequency power supply to the first and the second electrode to limit power reflected back to the high-frequency power supply. In some embodiments a flexible conduit connects the housing to the high-frequency power supply such that the housing is movable independent from the high-frequency power supply.

In further embodiments of the invention a distributor is mounted near the outlet of the housing for injecting a chemical precursor into the reactive species flowing out of the gas outlet of the housing.

The present invention is further embodied in a method of treating surfaces of three-dimensional objects of any size and shape with the low temperature, atmospheric pressure plasma. The method comprises flowing a gas through a non-conducting housing, applying a high-frequency signal to one or more electrodes that are positioned substantially along the length of the housing, matching the impedance of the power input to the gas so as to strike and maintain a uniform plasma, and placing an object downstream of the outlet of the housing such that the flowing plasma gas contacts the object and treats its surface. The invention is further embodied in a method of treating surfaces with the low-temperature, atmospheric pressure plasma, wherein the treatment causes the surface to be activated, cleaned, sterilized, etched, or coated with a thin film.

A typical method embodiment of producing an atmospheric pressure plasma comprises the operations of flowing a gas into a gas inlet of a housing comprising a dielectric material, disposing a first electrode and a second electrode in opposition exterior to the housing, applying high-frequency power to at least one of the first electrode and the second electrode to ionize at least a portion of the gas to produce at least one reactive species, and flowing the at least one reactive species out of the gas outlet of the housing. The method may be further modified consistent with the apparatus embodiments, including variation of the duct and materials of the housing as well as the power supply.

The method may include matching an impedance of the high-frequency power to the electrodes to limit reflected power. The method may also include connecting the housing to a supply of the high-frequency power with at least one flexible conduit such that the housing is movable independent from the supply.

Typically, at least a portion of the gas flowing through the housing is selected from the group consisting of helium, argon, oxygen, nitrogen, hydrogen, ammonia, carbon monoxide, carbon dioxide, carbon tetrafluoride, sulfur hexafluoride, methane, acetylene, and mixtures thereof. The reactive species may be used to perform a surface treatment such as activation for adhesion, cleaning, etching, sterilization, chemical functionalization and thin film deposition.

In further embodiments, the method may include injecting a chemical precursor from a distributor near the gas outlet of the housing into the reactive species flowing out of the gas outlet of the housing. The chemical precursor may be deposited as a coating from the reaction of the chemical precursor with the reactive species onto an object placed downstream of the gas outlet of the housing.

### BRIEF DESCRIPTION OF THE DRAWINGS

Referring now to the drawings in which like reference numbers represent corresponding elements throughout:

FIG. 1 is a block diagram of the low temperature atmospheric pressure plasma in accordance with the present invention;

FIG. 2 is a schematic of an apparatus for generating the low temperature atmospheric pressure plasma using a non-conducting housing that comprises a quartz tube;

FIG. 3 is a schematic of an apparatus for generating the low temperature atmospheric pressure plasma using a linear array of non-conducting tubular housings;

FIG. 4A is a schematic of an apparatus for generating the low temperature atmospheric pressure plasma using a non-conducting tubular housing, in which gas is fed at both ends of the tube and the plasma exits through an array of holes along the side;

FIG. 4B is a schematic of an apparatus for generating the low temperature atmospheric pressure plasma using a non-conducting tubular housing, in which gas is fed at one end of the tube and the plasma exits through a slit along the side;

FIG. 5 is a schematic of an apparatus for generating the low temperature atmospheric pressure plasma using a non-conducting housing that comprises a rectangular quartz duct;

FIG. 6A is a schematic of the low temperature atmospheric pressure plasma device configured for the deposition of thin films according to the present invention;

FIG. 6B is a side-view of the apparatus shown in FIG. 6A;

FIG. 7 is a schematic of an apparatus for generating the low temperature atmospheric pressure plasma using a non-conducting tubular housing, in which the gas is fed at one end and the plasma exits through a nozzle at the other end to allow the reactive gas to treat a larger surface area;

FIG. 8A is a schematic of an apparatus for generating the low temperature atmospheric pressure plasma using a non-conducting rectangular duct, in which the gas is fed at one end and the plasma exits through a nozzle at the other end to allow the reactive gas to treat a larger area of an object;

FIG. 8B is a schematic of the low temperature atmospheric pressure plasma device that is configured for the deposition of thin films and contains a nozzle to promote mixing of the reactive gas with the chemical precursor;

FIG. 9 is a schematic of the low temperature atmospheric pressure plasma, according to the present invention, in which a circular plasma beam is used for the continuous in-line treatment of substrate surfaces;

FIG. 10 is a schematic of the low temperature atmospheric pressure plasma, according to the present invention, in which a linear plasma beam extending across the width of the substrate is used for continuous in-line surface treatment;

FIG. 11 is a schematic of the present invention configured for the treatment of disk-shaped substrates;

FIG. 12 shows a plot of the etch rate of silicon as a function of the amount of carbon tetrafluoride added to the argon plasma struck in the apparatus depicted in FIG. 2;

FIG. 13 presents a plot of the average deposition rate as a function of deposition time using the apparatus described in FIG. 6; and

FIG. 14 is a flowchart of an exemplary method embodiment of the invention.

### DETAILED DESCRIPTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

1.0 Overview

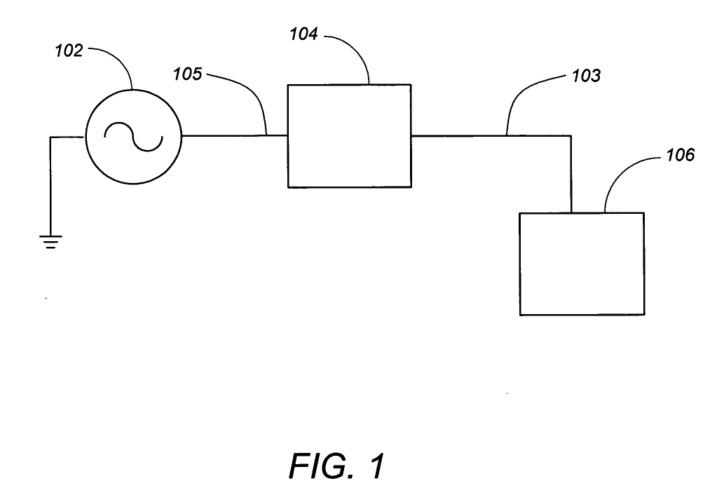

FIG. 1 shows a diagram of an exemplary embodiment of the present invention. The apparatus comprises a high-frequency power supply 102 connected via a flexible conduit 103 to a matching network 104, which is in turn connected via a second flexible conduit 105 to the plasma source 106. The plasma source 106 comprises a non-conducting housing with metal electrodes arranged along its exterior. The matching network ensures that most of the applied power is delivered to the electrodes in order to break down the gas, and not reflected back to the power supply. Furthermore, the high-frequency generator 102, together with the matching network 104, are capable of both striking and maintaining the discharge, and no further electric circuits are required. The plasma source 106 will be described in more detail in the accompanying figures as detailed hereafter.

2.0 Low Temperature Atmospheric Pressure Plasma

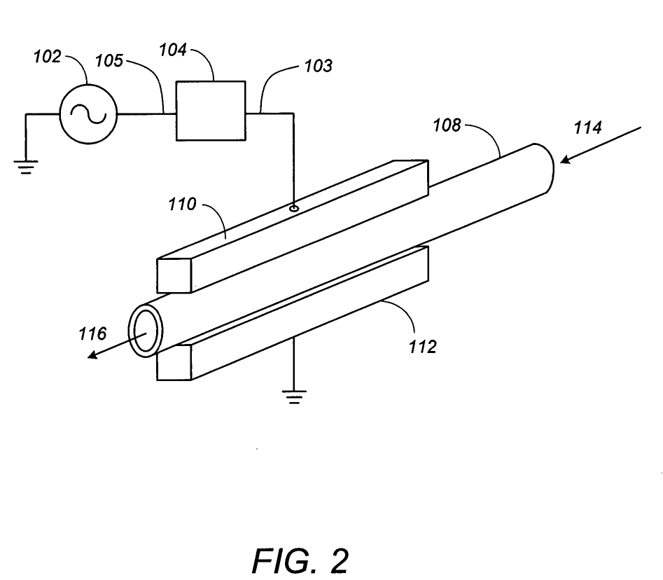

A schematic of the plasma apparatus is shown in FIG. 2. In this figure, the power supply 102 is connected to the tuning network 104 and then to the powered electrode 110. Power is supplied to electrode 110, while electrode 112 is grounded. A non-conducting tube 108 is placed in between the electrodes 110 and 112 to constrain the gas flow that is fed in at the inlet 114. Although the non-conducting housing is shown as a tube, it can also be square or rectangular in shape as described below. In fact with this design, there is no constraint on the shape of the non-conducting housing. The discharge is struck in the tube 108 along the length of the electrode when power is supplied to electrode 110. The plasma effluent exits the tube in a beam at the outlet 116 and can be directed onto a substrate placed a short distance downstream. The gas temperature at the outlet 116 is less than 400° C.

An embodiment of the present invention can be constructed with a non-conducting housing from a quartz tube with an outside diameter of 3 mm and a length of 8 inches. Powered and grounded electrodes comprising aluminum plates about 2.5 inches long by 0.75 inches wide by 0.125 inches thick can be mounted on each side of the quartz tube and connected to the power supply and matching network. Argon and 10.0 volume percent nitrogen can be fed to the housing at 20.0 L/min, and 170 W of radio frequency power at 13.56 MHz can be supplied to one of the electrodes. The discharge region can appear as a bright white glow along the tube where the electrodes are disposed. The reactive species can be seen as an orange glow that extended out of the plasma discharge an additional 4 inches down the quartz tube. Other materials and dimensions may be used for this plasma device without departing from the scope of the invention.

3.0 Low Temperature Atmospheric Pressure Plasma with Plurality of Housings

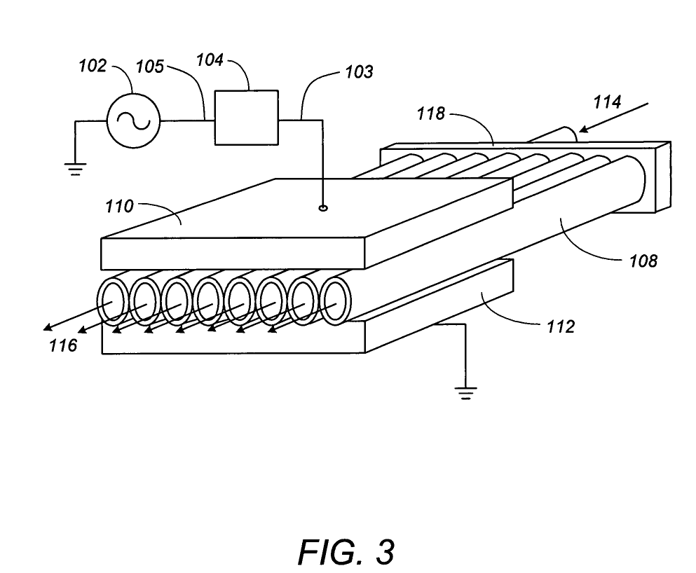

A exemplary embodiment of the present invention is a linear array of plasma sources as shown in FIG. 3. The non-conducting tubes 108 are placed side by side, and are sandwiched between the powered electrode 110 on top, and the grounded electrode 112 on the bottom. The powered electrode 110 is coupled to a matching network 104 and high-frequency power supply 102. The gas flow is introduced at the inlet 114, and divided evenly amongst the tubes using a distributed plate 118. The plasma is struck in the individual tubes and the reactive gas exits through the linear array of outlets 116. This configuration is advantageous for treating a strip of material. The material would be passed underneath the curtain of reactive plasma gas generated from the apparatus presented in FIG. 3. Although only eight tubes are shown in the figure, different numbers of tubes may be used, depending on the width of material to be treated.

The arrangement of the multiple non-conducting housings need not be limited to a linear array. They could be arranged in a circle, square, rectangle, polygon, or any other pattern, provided that the housings are uniformly contacted along a portion of their lengths with the powered and grounded electrodes, and that the gas flow is evenly distributed to each of the tubes. In addition, linear arrays of housings may be stacked one on top of the other separated by alternating powered and grounded electrodes. This would produce a large area plasma beam suitable for treating the surfaces of large substrates.

4.0 Low Temperature Atmospheric Pressure Plasma with Tangential Outlet

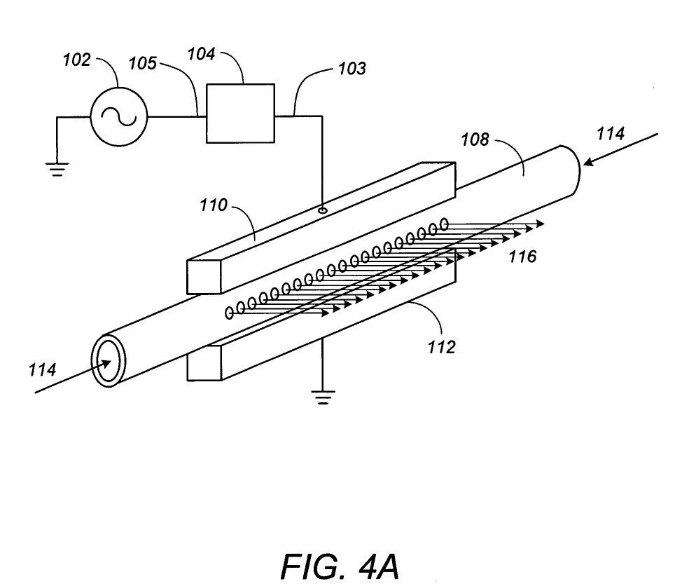

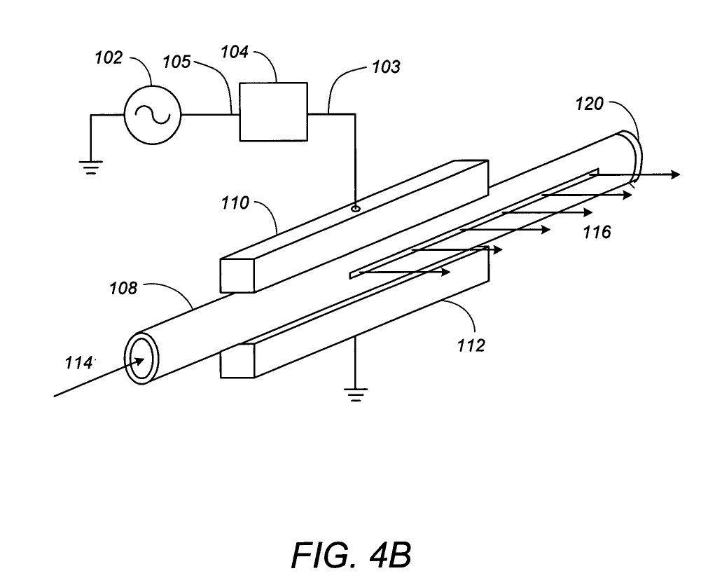

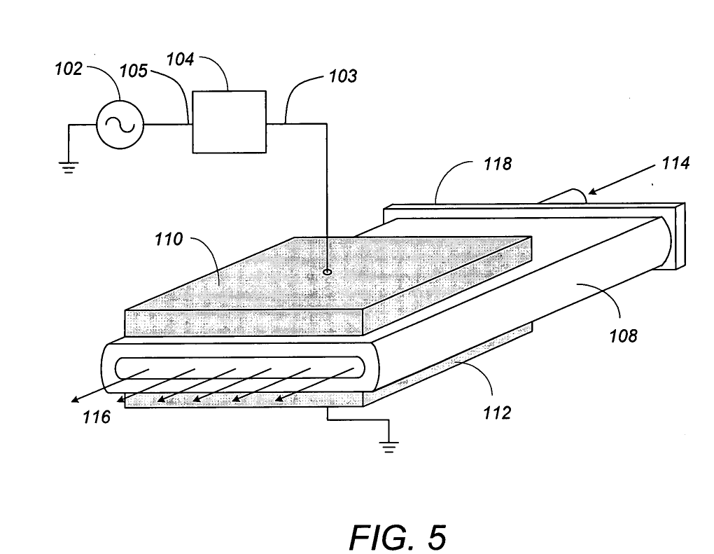

In one embodiment of the present invention the reactive gas is flowed from the plasma tangentially out the side of the non-conducting housing. This configuration of the low temperature, atmospheric pressure plasma is presented in FIGS. 5A and 5B. In the former case, the non-conducting tube 108 contains an array of outlets 116 along its side. The gas is fed into both ends of the housing at the inlets 114. The plasma is struck in the tube by applying an electrical signal from the power supply 102 and matching network 104 to the electrodes 110 and 112. The embodiment of the invention presented in FIG. 4B differs from that in FIG. 4A by the use of a slit outlet 116, instead of an array of holes. In addition, the gas is fed into only one end of the tube at 114, while the other end is terminated with a cap 120. The slit 116 can be placed at any position along the length of the non-conducting housing 108. For example, it may be placed at the same position as the electrodes 110 and 112, or at a position further downstream beyond the electrodes. The advantage of this design is that a sheet of reactive gas is generated that can rapidly treat a material surface as it is passed underneath the sheet. The length of the outlet array of holes or slit can be varied over a wide range without deviating from the scope of the invention.

5.0 Low Temperature Atmospheric Pressure Plasma with Rectangular Housing

A schematic of an exemplary plasma apparatus configured with a rectangular non-conducting housing is shown in FIG. 5. The power supply 102 is connected to the tuning network 104 and then to the electrode 110, while electrode 112 remains grounded. In an alternative embodiment, the tuning network 104 is connected to electrodes (110 and 112) so that power is delivered to both electrodes. The electrodes (110 and 112) are attached to the outside of the rectangular housing 108 that has a gas inlet 114 and outlet 116. The height of the gas channel inside the housing is between 0.1 and 5.0 mm, although other widths may be used without deviating from the scope of the present invention. The width of the gas channel, on the other hand, may be much larger than 5.0 mm, and is not limited to any particular size. When power is supplied to electrode 110, the gas discharge is struck uniformly inside the housing 108. The plasma exits the duct at the outlet 116, producing a sheet of reactive gas that can be directed onto a substrate placed between 0.2 and 5.0 cm downstream. The gas temperature at the outlet depends on the amount of applied power, but is generally close to 300° C.

6.0 Low Temperature Atmospheric Pressure Plasma for Depositing Coatings

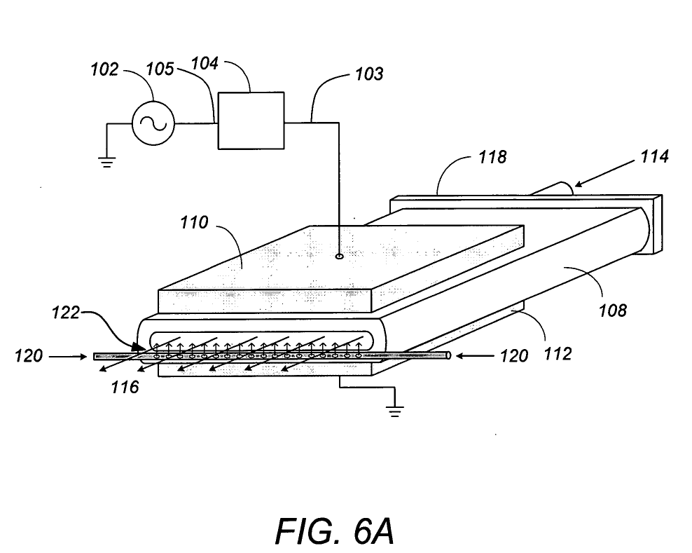

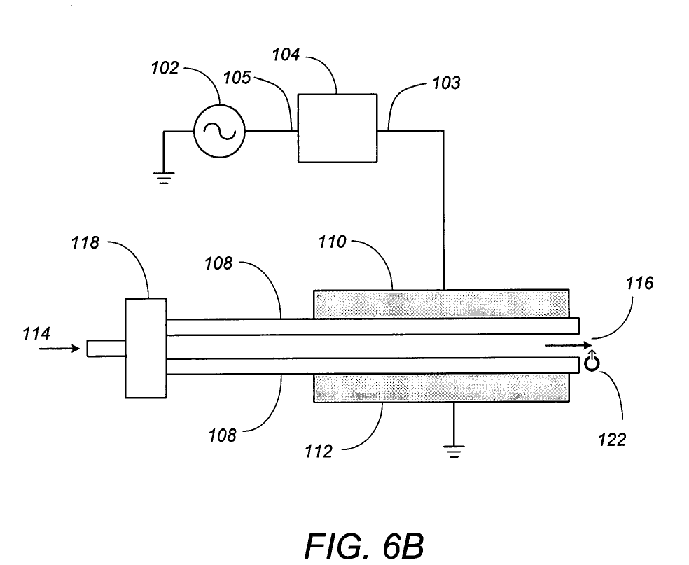

In FIG. 6A, a schematic is presented of an exemplary low temperature atmospheric pressure plasma configured for depositing coatings onto a substrate. A side-view of this apparatus is presented in FIG. 6B. A precursor distributor 122 has been mounted in front of the plasma outlet 116. Volatile chemical precursors are fed into the distributor inlet 120, and out through holes in the side, where they mix with the plasma effluent. Active species in the plasma effluent attack the chemical precursor, causing it to decompose and deposit a thin film on a substrate located a short distance downstream. For instance, the chemical precursor may be hexamethyldisiloxane. By mixing this molecule with the effluent from an oxygen and argon plasma, a silicon dioxide film (i.e., glass) may be deposited onto the substrate.

The apparatus shown in FIGS. 6A and 6B was constructed using a rectangular quartz duct measuring 6.4 cm long by 6.4 cm wide. The opening in the duct was 1.6 mm high, and the wall thickness was 1.6 mm as well. The powered and grounded electrodes mounted on each side of the quartz housing were made of aluminum and were 5.0×5.0 cm². The precursor distributor 122 was a stainless steel tube with a diameter of 1.5 mm. Thirty-five holes were drilled into the tube at an even spacing along a distance of 6.0 cm. A No. 80 drill was used for this purpose. The precursor distributor was placed 5.0 mm downstream of the quartz cell outlet 116. It is noted that one may use other materials, channel shapes and dimensions for the non-conducting housing without departing from the scope of the present invention.

7.0 Low Temperature Atmospheric Pressure Plasma with Outlet Nozzle

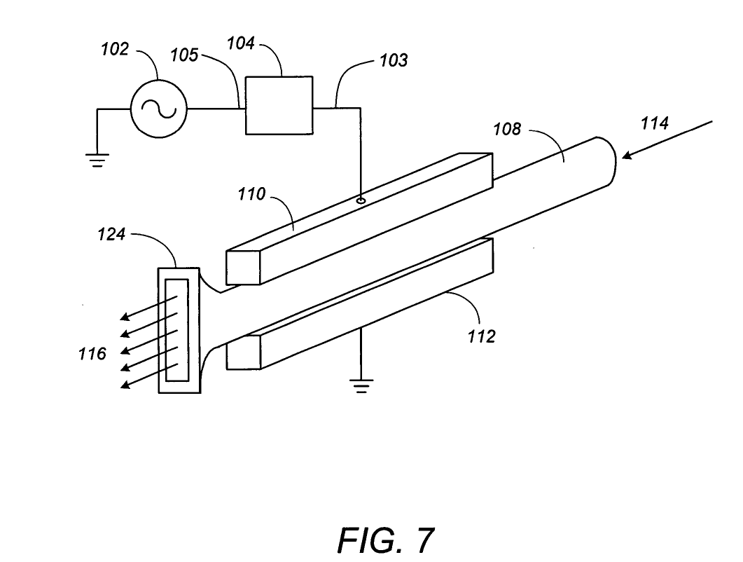

Another exemplary embodiment of the atmospheric pressure plasma is shown in FIG. 7. Here, the gas is passed through a non-conducting tubular housing 108 and is exhausted out a nozzle 124. The nozzle 124 expands the cross-sectional area for flow of the reactive gas so that it can contact a larger area of a substrate. A linear flow pattern is shown in the drawing of FIG. 7. However, many other nozzle designs may be employed without deviating from the scope of the invention. The nozzle 124 may be fashioned with an orifice that is smaller than the internal dimension of the gas housing 108. For example, the orifice could be 50 microns in diameter, so that one could use the low temperature, atmospheric pressure plasma to etch a 50 micron groove into a substrate.

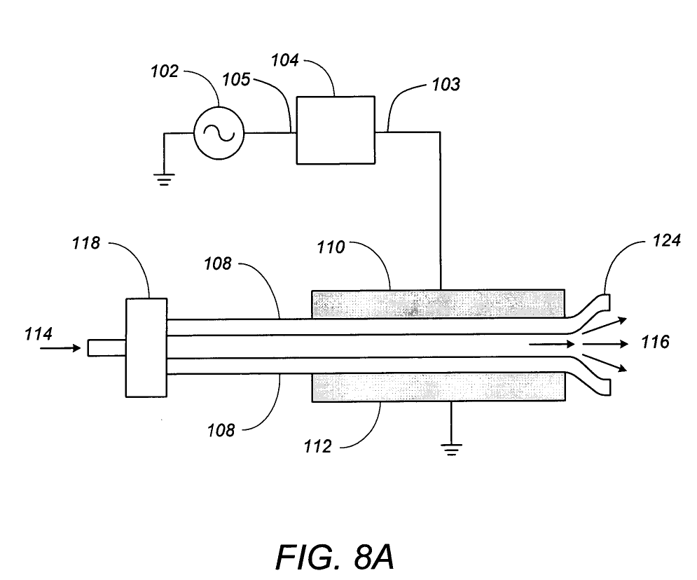

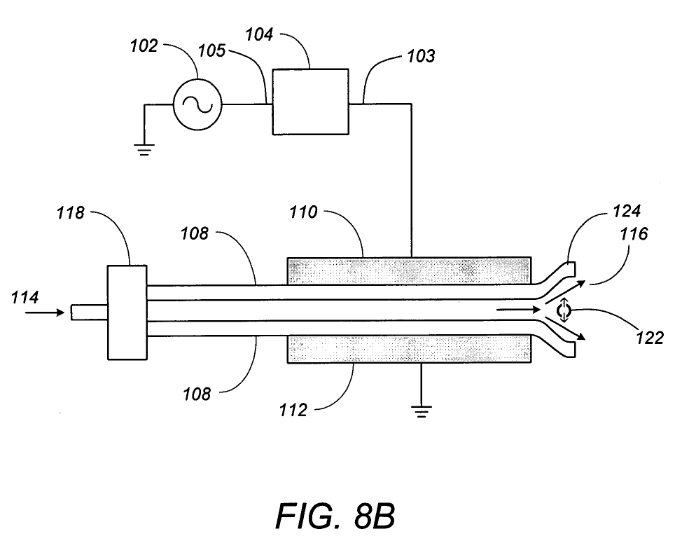

Shown in FIG. 8A is a schematic of the atmospheric pressure plasma device that utilizes a non-conducting rectangular housing 108. Here, the gas passes through the housing 106 and out the nozzle 124. The nozzle expands the cross-sectional area for flow of the gas so that it can contact a larger strip of the substrate. Alternatively, the outlet of the non-conducting rectangular housing 108 may be equipped with an outlet nozzle 124, and a precursor distributor 122 that is positioned within the nozzle. This embodiment of the invention is illustrated in FIG. 8B. The distributor pipe contains two arrays of holes that cause the chemical precursor to flow out the top and bottom of the distributor. This improves the mixing between the plasma effluent and the precursor, so the film is deposited faster and more uniformly onto the substrate. Many other nozzle designs may be employed without deviating from the scope of the present invention.

8.0 Processing Substrates

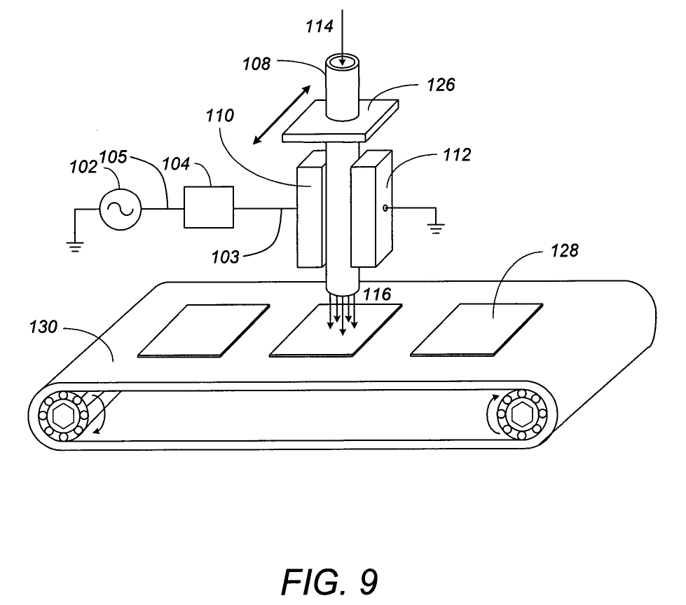

Other embodiments of the present invention comprise a technique of using the low temperature atmospheric pressure plasma for the continuous in-line surface treatment of materials. One way in which this invention may be practiced is shown in FIG. 9. The plasma tool, comprising a power supply 102, matching network 104, flexible conduits 103 and 105, non-conducting housing 108, electrodes 110 and 112, gas inlet 114, and gas outlet 116, is mounted on a mechanical stage 126. The flexible conduits 103 and 105 connect the power supply and matching network to the electrodes 110 and 112. In a preferred embodiment these flexible conduits 103 and 105 also may comprise a flexible plastic tubing to supply the gas flow to the gas inlet 114. The substrates 128 are placed on a conveyor 130. As the substrates 128 move continuously down the conveyor 130, the plasma tool rapidly scans over their surfaces, providing them with a uniform treatment.

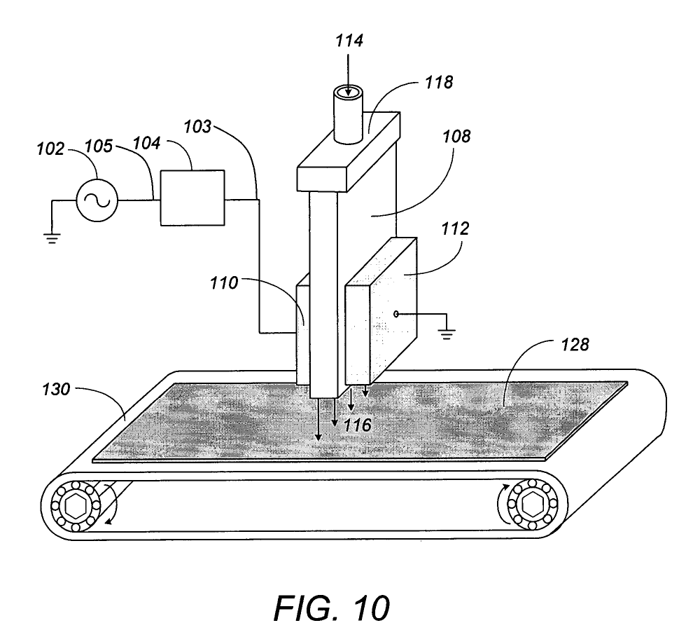

Another exemplary embodiment of the present invention is shown in FIG. 10. Here, the plasma tool comprises a high-frequency power supply 102, matching network 104, non-conducting rectangular housing 108, electrodes 110 and 112, gas inlet 114, and gas outlet 116. This tool is suspended over a substrate 128 that consists of a continuous sheet of material. The width of the plasma beam emanating from the gas outlet 116 is equal to or slightly larger than the width of the substrate 128. The conveyor 130 translates the substrate 128 underneath the plasma beam so that its surface is rapidly and uniformly treated. The plasma tool may scan over the surface of the moving substrate as well. In this case, the power connection from the power supply 102 to the electrodes 110 and 112 would be housed in the flexible conduit 103. This conduit 103 may also include a plastic tubing that connects the gas supply to the gas inlet 114 of the plasma tool.

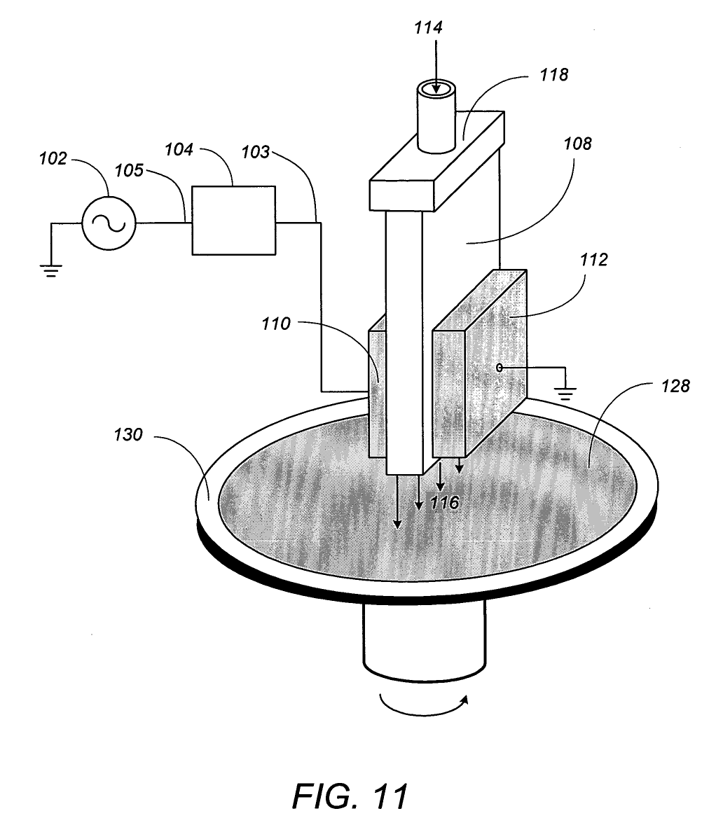

The low temperature atmospheric pressure plasma is well suited for treating substrates of different shapes. For example, the apparatus presented in FIG. 11 may be used for uniformly treating a circular substrate 128. In this case, the substrate 128 is placed on a rotational stage 130. The width of the plasma beam 116 may be chosen to be any convenient size up to and including the diameter of the substrate to be processed. In addition, the plasma tool may be mounted on a moving stage and translated back and forth over the substrate 128 as it rotates underneath the plasma beam. In this case, the power supply 102 and matching network 104 may be connected to the electrode 110 via flexible conduits 103 and 105 to facilitate scanning of the plasma source over the substrate 126. In a further embodiment, these flexible conduits 103 and 105 also may include flexible plastic tubing to supply the gas flow to the gas inlet 114. Any number of alternate configurations may be used consistent with the present invention to achieve uniform surface treatment in a short processing time as shall be understood by those skilled in the art.

In yet another embodiment of the present invention, the plasma tool may be mounted on an x-y-z mechanical stage that is manually operated, or computer controlled, as in the case of a robotic arm. The substrate to be treated may be a three-dimensional object with no restriction on its size or shape. The plasma tool would be used to treat selected areas of the three-dimensional object. For example, the atmospheric plasma could be configured with a 50-micron outlet nozzle, and be fed with a mixture of argon and fluorine-containing gas molecules, e.g., carbon tetrafluoride, to generate a directed beam of fluorine atoms. This beam could be used to etch 50 micron grooves around the circumference of a glass rod. Such a three-dimensional etching tool would have valuable applications in micro machining. In yet another example, the atmospheric plasma could be configured with a 2 to 4 inch wide beam, and be fed with a mixture of argon and oxygen-containing molecules, e.g., O₂, to generate a linear beam of oxygen atoms. This beam could be used to rapidly scan over the surface of a plastic automobile bumper. An automobile bumper treated this way the atmospheric plasma tool would accept paint much better so that the coating is more uniform and adheres more strongly to the plastic surface.

### EXAMPLE 1

### Etching Polyimide

As an example of how one may practice the present invention, the apparatus shown in FIG. 2 was used to etch polyimide films. A mixture of argon and 5.5 volume percent oxygen was fed into a quartz tube, 3.0 mm in diameter, at a total flow rate of 4.6 L/min. Power was supplied to one of the electrodes at 13.56 MHz, while the other electrode was grounded. In the first experiment, the length of the discharge zone was 1.0 inch, and the power input was 90 W. The polyimide was placed 2.5 mm away from the end of the tube, yielding a gas temperature at this position of about 290° C. An etch rate through the polymer of 1.3 microns per second was obtained. In the second experiment, the length of the discharge zone was 2.5 inches, and the power input was 130 W. The sample was placed 1.0 cm away from the end of the tube, where the gas temperature was approximately 290° C. In this case, the etching rate of the polyimide film was 4.2 microns per second. These rates may be compared to those achieved by atmospheric pressure plasmas described in the prior art, where polyimide films were stripped away at less than 0.15 microns per second. It is evident that embodiments of the present invention etch materials at much higher rates.

### EXAMPLE 2

### Etching Silicon

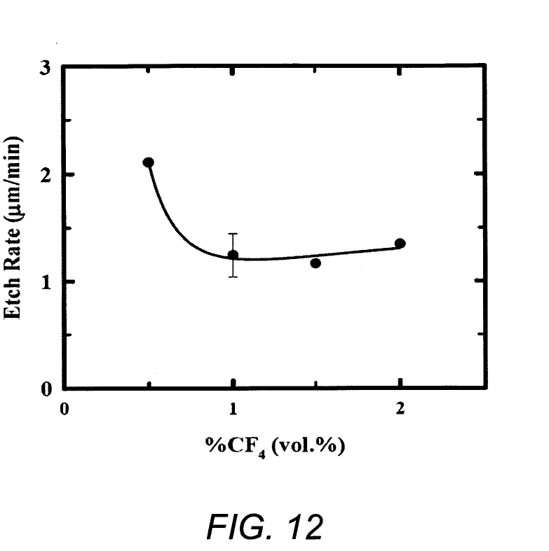

Silicon films were etched using the low temperature atmospheric pressure plasma depicted in FIG. 2. A quartz tube, 3 mm in diameter, was used in this experiment, and the length of the discharge zone was 2.5 inches. The plasma was fed with 5.0 L/min argon and varying amounts of carbon tetrafluoride (CF₄) between 0.5 and 2.3 volume percent. Upon applying 160 W/cm³ to the gas volume between the electrodes, a discharge was struck that yielded an extremely bright green glow. A silicon wafer was placed 1 cm downstream of the outlet of the quartz housing, and the plasma beam was allowed to impinge on the wafer for several minutes. Afterwards, the depth of the hole etched into the wafer was measured with a Deptak profilometer. The results of this experiment are presented in FIG. 12. A silicon etch rate of about 2.0 microns per minute was achieved with 0.5 volume percent CF₄, whereas between 1.0 and 2.0 volume percent CF₄, the etch rate averaged 1.3 microns per minute. It is likely that the fluorine plasma also etched the quartz tube. The reaction with the tube walls may have reduced the rate of the silicon etching process. This problem may be overcome by employing sapphire instead of quartz for the non-conducting housing.

It should be noted that the method and apparatus describe herein is not limited to etching polyimide and silicon. Many other materials may be removed using the present invention. For example, to etch tungsten metal, a fluorine plasma can be made by feeding carbon tetrafluoride or sulfur hexafluoride and an inert gas into the discharge. The reactive species produced by the discharge are expected to produce gaseous WF₆ molecules and etch the tungsten metal at a high rate. Other materials that may be etched with the oxygen plasma are polymer films, including, but not limited to, polyethylene, polystyrene, polyacrylonitrile, polyaniline, polyetheretherketone and nylon, as well as carbon-fiber-reinforced composites. Other materials that may be etched with fluorine plasmas include, buy are not limited to, silicon dioxide (glass), silicon nitride, silicon oxynitride, tantalum, molybdenum, uranium, tungsten oxide, tantalum oxide, molybdenum oxide, and uranium oxide.

### EXAMPLE 3

### Surface Activation

Another example of how one may practice the present invention is to modify the surface of plastic or other materials. For example, the discharge can be used to change the wettability of the surface. In this case, a hydrophobic material can be processed to become more hydrophilic or visa versa by treating it with oxygen or hydrogen plasmas. By making a plastic surface more hydrophilic, it can better accept paints or inks for printing, and glue for making strong adhesive bonds.

Plastic samples were treated with the apparatus shown in FIG. 2 under the following conditions: 5.0 L/min argon gas flow, 0.2 L/min oxygen gas flow, 200 W of power at 13.56 MHz, and a distance from the plasma outlet to the sample of about 1.0 cm. The plasma exposure time was 0.5 seconds. Before and after plasma treatment, the surface energy of each material was measured with Accu Dyne Test markers. It was found that the surface energies changed as follows: polypropylene increased from 40 to greater than 70 dyne/cm, nylon increased from 38 to greater than 70 dyne/cm, silicone increased from less than 30 to greater than 70 dyne/cm, polycarbonate increased from 56 to greater than 70 dyne/cm, polystyrene increased from 56 to greater than 70 dyne/cm, and acrylonitrile-butadiene-styrene increased from 34 to greater than 70 dyne/cm. For reference, a water droplet will spread out flat on a material with a surface energy greater than 70 dyne/cm.

To demonstrate that surface activation can be carried out on materials other than plastic using the present invention, a tin plate was processed with the apparatus depicted in FIG. 2. The conditions were 5.5 volume percent oxygen in Argon, 4.6 L/min total flow rate, 5-inch glass tube, 250 W total power, and 5 mm distance from the plasma outlet to the sample. The wetting angle as observed by a water droplet test was 90° before treatment and 50° after a 1.0 second exposure to the plasma.

### EXAMPLE 4

### Sterilization of Materials

In another embodiment of the present invention, the low temperature atmospheric pressure plasma may be used to sterilize surfaces by removing bacteria and other harmful biological organisms. For example, the discharge may be used to clean medical equipment, operating rooms in hospitals, or equipment and facilities that have been subjected to a terrorist attack. In addition, the low temperature atmospheric pressure plasma should be an effective tool for the food industry to maintain clean and sterile materials, equipment and facilities involved in the processing and packaging of food.

### EXAMPLE 5

### Deposition of Thin Films

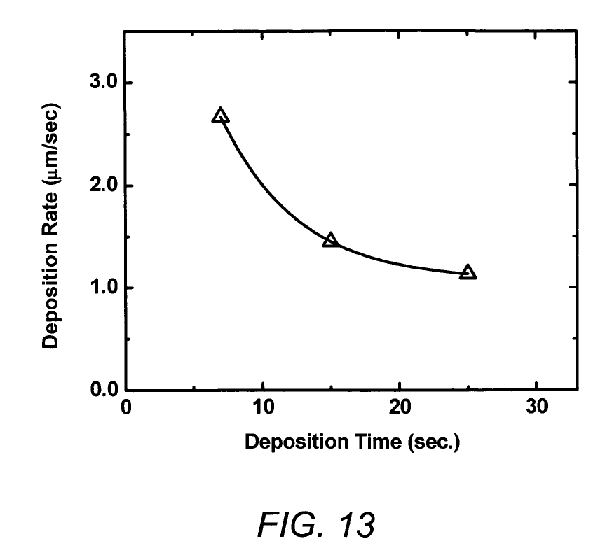

The apparatus shown in FIG. 6 was used to deposit glass films on silicon wafers. A mixture of argon and 3.0 volume percent oxygen was fed into the rectangular quartz duct (6.4 cm long by 6.4 cm wide) at a total flow rate of 80.0 L/min. A total power of 500 W at 13.56 MHz was supplied to both of the electrodes in order to strike and maintain the discharge. Hexamethyldisiloxane was dispersed into argon carrier gas and introduced to the apparatus through the precursor distributor 122 located 5.0 mm away from the outlet of the duct. A silicon wafer was placed on a holder 6.0 mm downstream of the distributor, and spun at a rate of 150 RPM. Shown in FIG. 13 is a plot of the average deposition rate as a function of the deposition time. Average rates of 2.7, 1.5 and 1.1 microns per second were obtained for total exposure times of 7.0, 15.0 and 25.0 seconds. Other silane precursors may be used for this process, such as tetraethoxysilane, tetramethyldisiloxane, hexamethyldisilazane, trichlorosilane, and any volatile silane molecule containing ligands with C, O, N, H or Cl atoms, as understood by those skilled in the art.

The deposition rates obtained with the present invention may be compared to those recorded using atmospheric pressure plasmas described in the prior art. The rates reported in the prior art are generally less than 0.01 microns per second. For example, Babayan et al. in Plasma Sources Science and Technology, vol. 7, page 286 (1998) reported a maximum glass deposition rate of 0.005 microns per second using an atmospheric pressure plasma jet. It is evident that the present invention deposits thin films at much higher rates than reported previously, and therefore is an important advancement in coating technology.

Differences were visually apparent resulting from the deposition of the glass films onto aluminum coupons (3.0×1.5 cm²) using the low-temperature atmospheric pressure plasma described in FIG. 6. The samples were rotated at 150 RPM underneath the plasma beam. Before deposition, the coupon was a uniform silver color. After deposition for 7.0 and 15.0 seconds, one was able to observe on the coupons rings of blue, yellow and red generated by a slight variation in the thickness of the glass film along the radial direction. The thickness variation occurred because the design of the precursor distributor had not been optimized for uniform mixing. Nevertheless, relatively thick glass films were deposited on the aluminum coupons in a short period of time.

Many different materials may be deposited using the low temperature atmospheric pressure plasma, including, organic, inorganic and metallic thin films. The only requirement is that at least one of the elements required in the film can be fed to the device through a volatile chemical precursor. Thin film materials that may be deposited using this method include, but are not limited to, polymers, metals, metal oxides, metal nitrides, metal carbides, and metal phosphides.

Examples of polymer films that may be deposited with embodiments of the present invention include, but are not limited to, polyethylene, polytetrafluoroethylene, and polyaniline. Examples of metals that may be deposited by the present invention include, but are not limited to, tungsten, titanium, copper, platinum, and gold. In the deposition of polymers and metals, it may be advantageous to feed hydrogen to the plasma source, and have the H atoms produced thereby react with the chemical precursor and deposit the desired film.

Specific metal oxides, nitrides and carbides that may be deposited by the present invention include, but are not limited to, zirconium oxide, tantalum oxide, titanium oxide, hafnium oxide, aluminum oxide, zinc oxide, indium-tin oxide, silicon nitride, titanium nitride, boron nitride, gallium nitride, silicon carbide, and tungsten carbide. For the deposition of metal oxides, nitrides and carbides, it may be desirable to feed oxygen, nitrogen, and acetylene, respectively to the atmospheric pressure plasma. The O, N or C atoms generated in the plasma will react with the chemical precursor and deposit the desired oxide, nitride or carbide thin film.

In addition, embodiments of the present invention may be used to deposit semiconductors, including, but not limited to, polycrystalline silicon, amorphous hydrogenated silicon, gallium arsenide, and indium phosphide. As an example of how to deposit amorphous hydrogenated silicon, one would feed to the plasma hydrogen and argon gas, then combine the effluent from the plasma with silane, and impinge this reaction mixture onto a heated glass substrate. A uniform film would be deposited by translating the substrate underneath the plasma beam, such as is shown in FIG. 10. A wide variety of films may be deposited according to the present invention, and would be understood by those skilled in the art.

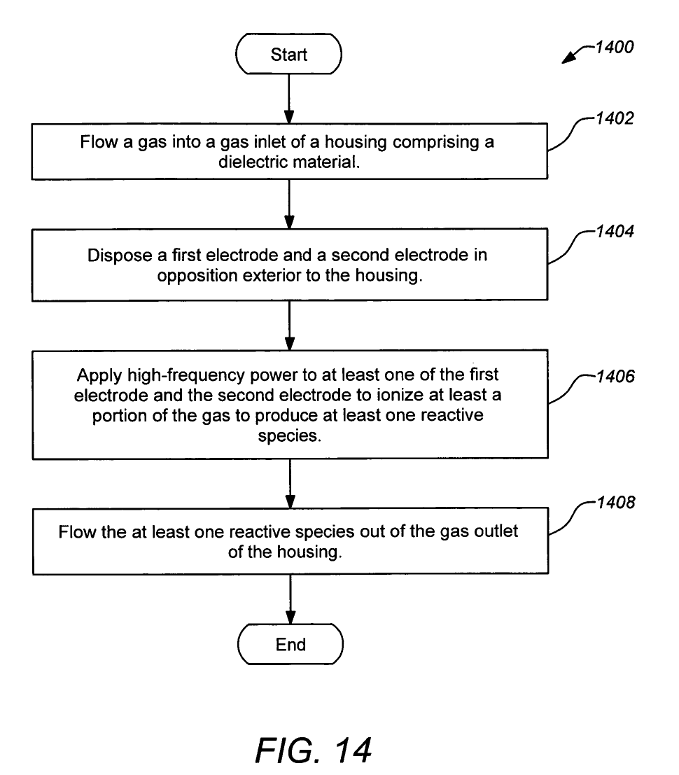

FIG. 14 is a flowchart of an exemplary method 1400 embodiment of the invention. The method 1400 begins by flowing a gas into a gas inlet of a housing comprising a dielectric material in operation 1402. In operation 1404, a first electrode and a second electrode are disposed in opposition exterior to the housing. Next in operation 1406, high-frequency power is applied to at least one of the first electrode and the second electrode to ionize at least a portion of the gas to produce at least one reactive species. In operation 1408, the reactive species flows out of the gas outlet of the housing. The method 1400 may be further modified consistent with any of the foregoing description as will be understood by those skilled in the art. For example, in a further embodiment an impedance of the high-frequency power may be matched to the at least one of the first electrode and the second electrode to limit reflected power. In addition, a chemical precursor from a distributor may be injected near the gas outlet of the housing into the at least one reactive species flowing out of the gas outlet of the housing. The chemical precursor may be deposited as a coating from the reaction of the chemical precursor with the reactive species onto an object placed downstream of the gas outlet of the housing.

The foregoing description including the preferred embodiment of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto. The above specification, examples and data provide a complete description of the manufacture and use of the invention. Since many embodiments of the invention can be made without departing from the scope of the invention, the invention resides in the claims hereinafter appended.

What is claimed is:

1. An atmospheric pressure plasma device, comprising:
a housing comprising a dielectric material having a gas inlet and a gas outlet;
a first electrode exterior to the housing;
a second electrode exterior to the housing and opposed to the first electrode; and
a high-frequency power supply coupled to at least one of the first electrode and the second electrode and operable to ionize at least a portion of a gas flowing from the gas inlet to the gas outlet of the housing to produce at least one reactive species flowing out of the gas outlet of the housing.

2. The plasma device of claim 1, wherein the housing comprises a tubular duct.

3. The plasma device of claim 2, wherein the tubular duct includes an inner diameter approximately between 0.1 and 5.0 millimeters.

4. The plasma device of claim 1, wherein the housing comprises a rectangular duct.

5. The plasma device of claim 4, wherein the rectangular duct includes an inner height approximately between 0.1 and 5.0 millimeters.

6. The plasma device of claim 1, wherein the dielectric material is selected from the group consisting of quartz and sapphire.

7. The plasma device of claim 1, wherein the at least one reactive species flowing out of the gas outlet of the housing has a temperature less than approximately 500° C.

8. The plasma device of claim 1, wherein the high-frequency power supply provides electrical power at n times of approximately 13.56 megahertz, where n is an integer ranging from 1 to 20.

9. The plasma device of claim 1, further comprising at least one flexible conduit connecting the housing to the high-frequency power supply such that the housing is movable independent from the high-frequency power supply.

10. The plasma device of claim 1, further comprising a distributor mounted near the outlet of the housing for injecting a chemical precursor into the at least one reactive species flowing out of the gas outlet of the housing.

11. A method of producing an atmospheric pressure plasma comprising:
flowing a gas into a gas inlet of a housing comprising a dielectric material;
disposing a first electrode and a second electrode in opposition exterior to the housing;
applying high-frequency power to at least one of the first electrode and the second electrode to ionize at least a portion of the gas to produce at least one reactive species; and
flowing the at least one reactive species out of the gas outlet of the housing.

12. The method of claim 11, wherein the housing comprises a tubular duct.

13. The method of claim 12, wherein the tubular duct includes an inner diameter approximately between 0.1 and 5.0 millimeters.

14. The method of claim 11, wherein the housing comprises a rectangular duct.

15. The method of claim 14, wherein the rectangular duct includes an inner height approximately between 0.1 and 5.0 millimeters.

16. The method of claim 11, wherein the dielectric material is selected from the group consisting of quartz and sapphire.

17. The method of claim 11, wherein the at least one reactive species flowing out of the gas outlet of the housing has a temperature less than approximately 500° C.

18. The method of claim 11, wherein the high-frequency power is provided at n times of approximately 13.56 megahertz, where n is an integer ranging from 1 to 20.

19. The method of claim 11, further comprising connecting the housing to a supply of the high-frequency power with at least one flexible conduit such that the housing is movable independent from the supply.

20. The method of claim 11, wherein a least a portion of the gas flowing through the housing is selected from the group consisting of helium, argon, oxygen, nitrogen, hydrogen, ammonia, carbon monoxide, carbon dioxide, carbon tetrafluoride, sulfur hexafluoride, methane, acetylene, and mixtures thereof.

21. The method of claim 11, wherein the at least one reactive species is used to perform a surface treatment selected from the group consisting of activation, cleaning, etching, sterilization, chemical functionalization, and thin film deposition.

22. The method of claim 11, further comprising injecting a chemical precursor from a distributor near the gas outlet of the housing into the at least one reactive species flowing out of the gas outlet of the housing.

23. The method of claim 22, further comprising depositing a coating onto an object placed downstream of the gas outlet of the housing from a reaction of the chemical precursor with the at least one reactive species.
